(19) United States
(12) Patent Application Publication
(10) Pub. No.: US 2025/0338523 A1
(43) Pub. Date: Oct. 30, 2025

(54) SEMICONDUCTOR DEVICE AND METHOD FOR FORMING THE SAME

(71) Applicant: Winbond Electronics Corp., Taichung City (TW)

(72) Inventors: Pei-Hsiu Peng, Kaohsiung City (TW); Hung-Yu Wei, Kaohsiung City (TW); Shuo-Che Chang, Taichung City (TW)

(73) Assignee: Winbond Electronics Corp., Taichung City (TW)

(21) Appl. No.: 18/817,913

(22) Filed: Aug. 28, 2024

(30) Foreign Application Priority Data
Apr. 29, 2024 (TW) 113115949

(51) Int. Cl. H01L 23/522

(52) U.S. Cl. CPC H10D 1/692; H01L 23/5223

(57) ABSTRACT

A semiconductor device includes a substrate, a first bottom electrode, a first storage capacitor, a first top electrode, a second bottom electrode, a second storage capacitor, and a second top electrode. The first bottom electrode is disposed over the substrate. The first storage capacitor is disposed over the first bottom electrode. The first top electrode is disposed over the first storage capacitor. The second bottom electrode is disposed over, and electrically coupled to, the first top electrode. The second storage capacitor is disposed over the second bottom electrode. The second storage capacitor vertically overlaps the first storage capacitor. The second top electrode is disposed over the second storage capacitor.

### CROSS REFERENCE TO RELATED APPLICATIONS

This Application claims priority of Taiwan Patent Application No. 113115949, filed on Apr. 29, 2024, the entirety of which is incorporated by reference herein.

### BACKGROUND OF THE INVENTION

### Field of the Invention

The present invention relates to semiconductor manufacturing, and, in particular, to semiconductor devices and methods for forming the same.

### Description of the Related Art

Semiconductor devices are widely used in various electronic products, such as personal computers, mobile phones, digital cameras and other electronic equipment. Although electronic components such as transistors and resistors are getting smaller, capacitors still take up more space than other electronic components due to their physical characteristics. This makes it difficult to miniaturize semiconductor devices. Therefore, there is a need to further improve semiconductor devices.

### BRIEF SUMMARY OF THE INVENTION

The present invention provides a semiconductor device. The semiconductor device includes a substrate, a first bottom electrode, a first storage capacitor, a first top electrode, a second bottom electrode, a second storage capacitor, and a second top electrode. The first bottom electrode is disposed over the substrate. The first storage capacitor is disposed over the first bottom electrode. The first top electrode is disposed over the first storage capacitor. The second bottom electrode is disposed over the first top electrode. The second bottom electrode is electrically coupled to the first storage capacitor. The second storage capacitor is disposed over the second bottom electrode. The second storage capacitor vertically overlaps the first storage capacitor. The second top electrode is disposed over the second storage capacitor.

The semiconductor device includes a substrate, a first bottom electrode, a first storage capacitor, a first top electrode, a second bottom electrode, a second storage capacitor, and a second top electrode. The first bottom electrode is disposed over the substrate. The first storage capacitor is disposed over the first bottom electrode. The first top electrode is disposed over the first storage capacitor. The second bottom electrode is disposed over the first top electrode and is electrically coupled to the first bottom electrode. The second storage capacitor is disposed over the second bottom electrode and vertically overlaps the first storage capacitor. The second top electrode is disposed over the second storage capacitor and is electrically coupled to the first top electrode.

The method of forming a semiconductor device includes forming a first capacitor structure over a substrate, including: forming a first bottom electrode; forming a first storage capacitor over the first bottom electrode; and forming a first top electrode over the first storage capacitor. The method of forming a semiconductor device also includes forming a first dielectric layer to cover the first capacitor structure. The method of forming a semiconductor device also includes forming a plurality of conductive vias in the first dielectric layer. The method of forming a semiconductor device also includes forming a second capacitor structure over the first dielectric layer, including: forming a second bottom electrode; forming a second storage capacitor over the second bottom electrode; and forming a second top electrode over the second storage capacitor. The second capacitor structure vertically overlaps the first capacitor structure and is electrically coupled to the first capacitor structure through the conductive vias.

### BRIEF DESCRIPTION OF THE DRAWINGS

FIGS. 1A-1C are cross-sectional views illustrating various stages of forming a semiconductor device in accordance with some embodiments.

FIGS. 2 and 3 are cross-sectional views illustrating semiconductor devices in accordance with some embodiments.

FIG. 4 is a top view illustrating a semiconductor device in accordance with some embodiments.

FIG. 5 is a circuit diagram illustrating a semiconductor device in accordance with some embodiments.

### DETAILED DESCRIPTION OF THE INVENTION

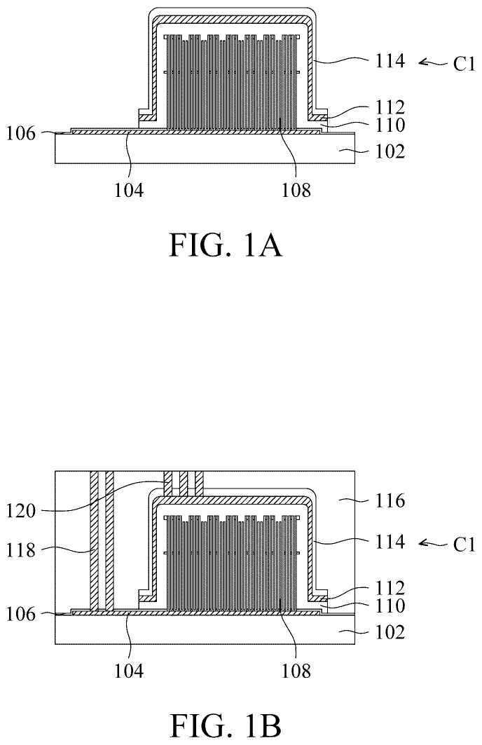

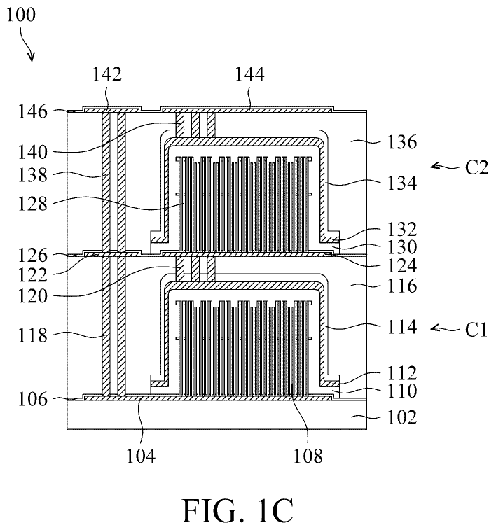

Referring to FIG. 1A, a semiconductor device 100 includes a substrate 102. The substrate 102 may be formed of any suitable substrate material for a semiconductor device, and may be a bulk semiconductor substrate or may include a composite substrate formed of different materials.

A first bottom electrode 104 is formed over the substrate 102. The first bottom electrode 104 may be formed of metallic material, such as tungsten or any suitable material. An insulating layer 106 is formed over the first bottom electrode 104. The insulating layer 106 may cover the top surface and sidewalls of the first bottom electrode 104 and the top surface of the substrate 102. The insulating layer 106 may be formed of a dielectric material, such as silicon nitride or any suitable material.

A first storage capacitor 108 is formed over a portion of the first bottom electrode 104. The first storage capacitor 108 includes a plurality of cylindrical capacitors. The first storage capacitor 108 is disposed in a first conductive material 110. The first conductive material 110 may be formed of a doped semiconductor material, including boron-doped silicon germanium layer (BSiGe), doped polycrystalline silicon, the like, or a combination thereof.

A first top electrode 112 is formed over the first conductive material 110. The first top electrode 112 may be formed of a metallic material, such as tungsten or any suitable material. A mask layer 114 is formed over the first top electrode 112. The mask layer 114 may be formed of a dielectric material, such as silicon oxide. For example, the mask layer 114 may be formed of tetraethoxysilane (TEOS).

Then, a patterning process may be performed, including one or more lithography and etching processes, so that the sidewalls of the first conductive material 110, the first top electrode 112, and the mask layer 114 are substantially coplanar with each other.

After the patterning process, a sidewall of the first top electrode 112 may extend beyond a sidewall of the first bottom electrode 104, and another sidewall of the first top electrode 112 may be located over the top surface of the first bottom electrode 104. Thereafter, the first bottom electrode 104, the first storage capacitor 108, the first conductive material 110, the first top electrode 112, and the mask layer 114 may form a first capacitor structure C1.

As illustrated in FIG. 1B, a dielectric layer 116 may be formed to cover the first capacitor structure C1. The dielectric layer 116 may be formed of a dielectric material, such as silicon oxide. A plurality of openings may be etched in the dielectric layer 116, and a plurality of conductive vias 118 and 120 may be formed in the openings. The conductive vias 118 and 120 may be formed of a metallic material, such as tungsten or any suitable material. The conductive vias 118 may be electrically coupled to the first bottom electrode 104, and the conductive vias 120 may be electrically coupled to the first top electrode 112.

As illustrated in FIG. 1C, a second bottom electrode 124 is formed over the dielectric layer 116. A metal layer 122 may be formed during the formation of the second bottom electrode 124. The material of the metal layer 122 may include that of the second bottom electrode 124, such as tungsten. An insulating layer 126 may be formed after forming the metal layer 122 and the second bottom electrode 124.

Next, a second storage capacitor 128, a second conductive material 130, a second top electrode 132, and a mask layer 134 may be formed over the second bottom electrode 124 to form a second capacitor structure C2, which may be similar to the formation of the first capacitor structure C1, and will not be repeated. The second capacitor structure C2 may vertically overlap (i.e., overlap in a direction perpendicular to the top surface of the substrate 102) the first capacitor structure C1. In particular, the second storage capacitor 128 may vertically overlap the first storage capacitor 108. Opposite sidewalls of the second top electrode 132 may extend beyond opposite sidewalls of the first bottom electrode 104.

Then, a dielectric layer 136 is formed to cover the second capacitor structure C2, and a plurality of conductive vias 138 and 140 are formed in the dielectric layer 136. Next, metal layers 142, 144 and an insulating layer 146 may be formed over the dielectric layer 136. The metal layer 142 may be electrically coupled to the second bottom electrode 122 through the conductive vias 138, and may be electrically coupled to the first bottom electrode 104 through the conductive vias 118. The metal layer 144 may be electrically coupled to the second top electrode 132 through the conductive vias 140. The second bottom electrode 124 may be electrically coupled to the first top electrode 112 through the conductive vias 120. As such, the semiconductor device 100 may include the first capacitor structure C1 and the second capacitor structure C2 connected in series. Since the second capacitor structure C2 vertically overlaps the first capacitor structure C1, a higher breakdown voltage can be provided with the same area.

It should be understood that other capacitor structures can be formed over the second capacitor structure C2, so that the semiconductor device 100 can include more capacitor structures to provide an even higher breakdown voltage.

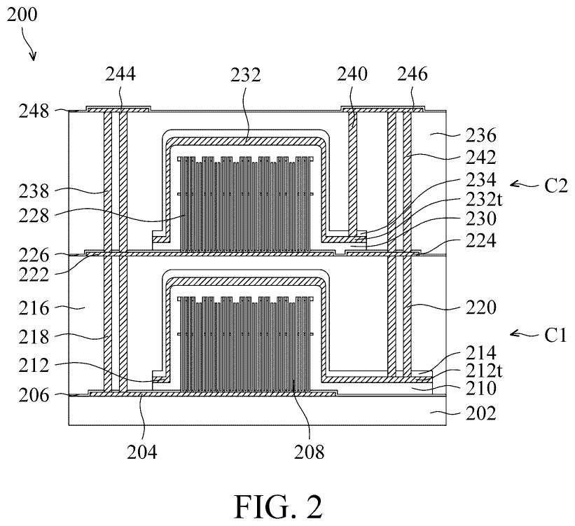

FIG. 2 is a cross-sectional view of a semiconductor device. Additional features can be added to semiconductor device 200. Some of the features described below can be replaced or eliminated for different embodiments. It should be noted that the semiconductor device 200 may include the same or similar components as that of the semiconductor device 100 in FIGS. 1A to 1C, and for the sake of simplicity, those components will not be discussed in detail again. In comparison the semiconductor device 100 in FIGS. 1A to 1C that includes capacitor structures connected in series, in the embodiment in FIG. 2, the semiconductor device 200 includes capacitor structures connected in parallel.

As illustrated in FIG. 2, the semiconductor device 200 includes a first capacitor structure C1 and a second capacitor structure C2 which are vertically stacked over a substrate 202. The formation of the first capacitance structure C1 and the second capacitance structure C2 of the semiconductor device 200 can be referred to the formation of the first capacitance structure C1 and the second capacitance structure C2 of the semiconductor device 100 in FIGS. 1A to 1C, and will not be repeated.

The first capacitor structure C1 may include a first bottom electrode 204, a first storage capacitor 208, a first conductive material 210, a first top electrode 212, and a mask layer 214. The first top electrode 212 may have a tail portion 212t on one side extending beyond a sidewall of the first bottom electrode 204, and the other side of the first top electrode 212 may be located over the top surface of the first bottom electrode 204. The semiconductor device 200 may include an insulating layer 206 covering the first bottom electrode 204, a dielectric layer 216 covering the first capacitor structure C1, and conductive vias 218, 220 passing through the dielectric layer 216.

The second capacitor structure C2 is disposed over the dielectric layer 216 and includes a second bottom electrode 222, a second storage capacitor 228, a second conductive material 230, a second top electrode 232, and a mask layer 234. The semiconductor device 200 may include a metal layer 224 disposed over the dielectric layer 216, an insulating layer 226 covering the second bottom electrode 222 and the metal layer 224, a dielectric layer 236 covering the second capacitor structure C2, and conductive vias 238, 240, 242 passing through the dielectric layer 236. The second top electrode 232 may have a tail portion 232t on one side extending beyond a sidewall of the second bottom electrode 222 and covering a portion of the metal layer 224. The length of the tail portion 212t of the first top electrode 212 may be greater than the length of the tail portion 232t of the second top electrode 232.

The semiconductor device 200 may include metal layers 244, 246, and an insulating layer 248 disposed over dielectric layer 236. The metal layer 244 may be electrically coupled to the second bottom electrode 222 through the conductive vias 238, and may be electrically coupled to the first bottom electrode 204 through the conductive vias 218. The metal layer 246 may be electrically coupled to the tail portion 232t of the second top electrode 232 through the conductive vias 240, electrically coupled to the metal layer 224 through the conductive vias 242, and electrically coupled to the tail portion 212t of the first top electrode 212 through the conductive vias 220. As such, the semiconductor device 200 may include the first capacitor structure C1 and the second capacitor structure C2 connected in parallel. Since the second capacitor structure C2 overlaps the first capacitor structure C1 in a direction perpendicular to the substrate 202, a higher capacitance can be provided with the same area.

It should be understood that other capacitor structures can be formed over the second capacitor structure C2, so that the semiconductor device 200 can include more capacitor structures to provide an even higher capacitance.

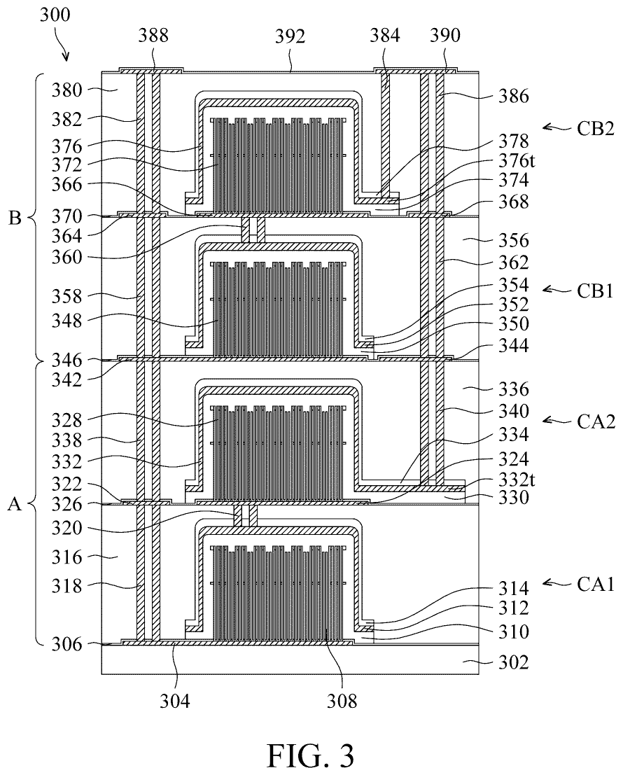

FIG. 3 is a cross-sectional view of a semiconductor device 300. Additional features can be added to semiconductor device 300. Some of the features described below can be replaced or eliminated for different embodiments. It should be noted that the semiconductor device 300 may include the same or similar components as that of the semiconductor device 100 in FIGS. 1A to 1C, and for the sake of simplicity, those components will not be discussed in detail again. In the embodiments of FIG. 3, the semiconductor device 300 includes a capacitor structures connected in series and in parallel.

As illustrated in FIG. 3, the semiconductor device 300 includes capacitor sets A and B that are vertically stacked and connected in parallel over the substrate 302. The capacitor set A may include capacitor structures CA1 and CA2 connected in series, and the capacitor set B may include capacitor structures CB1 and CB2 connected in series. The capacitor structure CA1 may include a bottom electrode 304, a storage capacitor 308, a conductive material 310, a top electrode 312, and a mask layer 314. The semiconductor device 300 may include an insulating layer 306 covering the bottom electrode 304, a dielectric layer 316 covering the capacitor structure CA1, and conductive vias 318, 320 passing through the dielectric layer 316.

The capacitor structure CA2 is disposed over the dielectric layer 316 and includes a bottom electrode 324, a storage capacitor 328, a conductive material 330, a top electrode 332, and a mask layer 334. The top electrode 332 may have a tail portion 332t on one side extending beyond a sidewall of bottom electrode 324. The semiconductor device 300 may include a metal layer 322 disposed over the dielectric layer 316, an insulating layer 326 covering the metal layer 322 and the bottom electrode 324, a dielectric layer 336 covering the capacitor structure CA2, and conductive vias 338, 340 passing through the dielectric layer 336.

The capacitor structure CB1 is disposed over the dielectric layer 336 and includes a bottom electrode 342, a storage capacitor 348, a conductive material 350, a top electrode 352, and a mask layer 354. The semiconductor device 300 may include a metal layer 344 disposed over the dielectric layer 336, an insulating layer 346 covering the bottom electrode 342 and the metal layer 344, a dielectric layer 356 covering the capacitor structure CB1, and conductive vias 358, 360, 362 passing through the dielectric layer 356.

The capacitor structure CB2 is disposed over the dielectric layer 356 and includes a bottom electrode 366, a storage capacitor 372, a conductive material 374, a top electrode 376, and a mask layer 378. The top electrode 376 may have a tail portion 376t on one side. The semiconductor device 300 may include metal layers 364, 368 on opposite sides of the bottom electrode 366, an insulating layer 370 covering the metal layers 364, 368 and the bottom electrode 366, a dielectric layer 380 covering the capacitor structure CB2, and conductive vias 382, 384, 386 passing through the dielectric layer 380.

The semiconductor device 300 may include metal layers 388, 390 and an insulating layer 392 disposed over the dielectric layer 380. The metal layer 388 may be electrically coupled to the metal layer 364 through the conductive vias 382, electrically coupled to the bottom electrode 342 through the conductive vias 358, electrically coupled to the metal layer 322 through the conductive vias 338, and electrically coupled to the bottom electrode 304 through the conductive vias 318. The metal layer 390 may be electrically coupled to the tail portion 376t of the top electrode 376 through the conductive vias 384, electrically coupled to the metal layer 368 through the conductive vias 386, electrically coupled the metal layer 344 through the conductive vias 362, and electrically coupled the tail portion 332t of the top electrode 332 through the conductive vias 340.

In addition, the bottom electrode 366 of the capacitor structure CB2 may be electrically coupled to the top electrode 352 of the capacitor structure CB1 through the conductive vias 360. The bottom electrode 324 of the capacitor structure CA2 may be electrically coupled to the top electrode 312 of the capacitor structure CA1 through the conductive vias 320. As such, the semiconductor device 300 may include the capacitor structures CA1 and CA2 connected in series, the capacitor structures CB1 and CB2 connected in series, and the capacitor sets A and B connected in parallel. Since the capacitor structures CB2 overlap the capacitor structures CA1, CA2, and CB1 in the direction perpendicular to the substrate 302, a higher breakdown voltage and a higher capacitance can be provided with the same area.

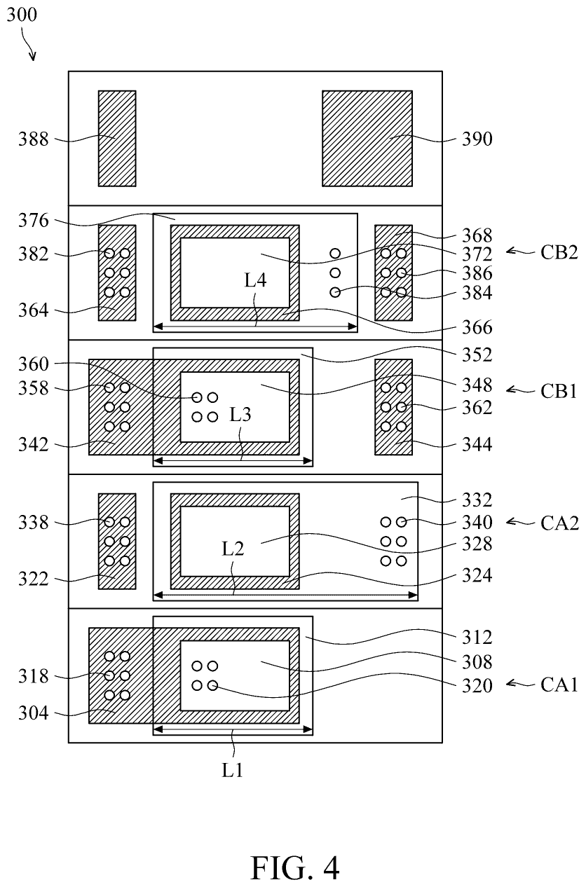

FIG. 4 is a top view illustrating each capacitor structure in the semiconductor device 300. To simplify the diagram, only a portion of the semiconductor device 300 is illustrated. As illustrated in FIG. 4, the length L2 of the top electrode 332 of the capacitor structure CA2 may be greater than the length L1 of the top electrode 312 of the capacitor structure CA1, the length L4 of the top electrode 376 of the capacitor structure CB2 may be greater than the length L3 of the top electrode 352 of the capacitor structure CB1, and the length L2 of the top electrode 332 of the capacitor structure CA2 may be greater than the length L4 of the top electrode 376 of the capacitor structure CB2.

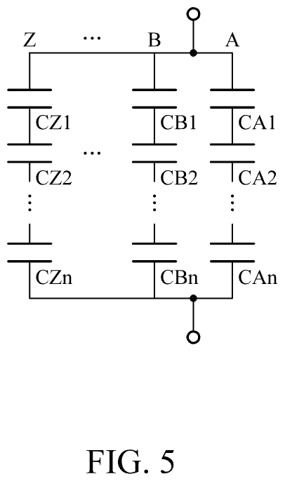

It should be understood that other capacitor structures can be formed over the capacitor structures CA2 and/or CB2, so that the semiconductor device 300 can include more capacitor structures, as illustrated in FIG. 5. For example, other capacitor structures (CA3 to CAn and CB3 to CBn) and capacitor sets (C to Z, each including capacitor structures CC1 to CCn . . . CZ1 to CZn) can be formed over the capacitor structures CA2 and CB2 to provide a higher breakdown voltage and a higher capacitance.

In summary, the semiconductor device provided by the embodiments of the present disclosure vertically stacks a plurality of capacitor structures, thereby increasing the breakdown voltage and the capacitance without increasing the occupied area.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first bottom electrode disposed over the substrate;
a first storage capacitor disposed over the first bottom electrode;
a first top electrode disposed over the first storage capacitor;
a second bottom electrode disposed over the first top electrode and electrically coupled to the first top electrode;
a second storage capacitor disposed over the second bottom electrode and vertically overlapping the first storage capacitor; and
a second top electrode disposed over the second storage capacitor.

2. The semiconductor device as claimed in claim 1, further comprising:
a first dielectric layer covering the first bottom electrode, the first storage capacitor, and the first top electrode;
an insulating layer disposed over the first dielectric layer; and
a second dielectric layer disposed over the insulating layer and covering the second bottom electrode, the second storage capacitor, and the second top electrode.

3. The semiconductor device as claimed in claim 2, further comprising:
a metal layer disposed between the first dielectric layer and the insulating layer; and
a conductive via passing through the first dielectric layer and electrically coupling the metal layer to the first bottom electrode.

4. The semiconductor device as claimed in claim 2, further comprising:
a conductive via disposed in the first dielectric layer and electrically coupling the first top electrode to the second bottom electrode.

5. The semiconductor device as claimed in claim 1, further comprising:
a mask layer covering the second top electrode, wherein a sidewall of the mask layer is aligned with a sidewall of the second top electrode.

6. The semiconductor device as claimed in claim 1, further comprising:
a third bottom electrode disposed over the second top electrode and electrically coupled to the first bottom electrode;
a third storage capacitor disposed over the third bottom electrode and vertically overlapping the first storage capacitor and the second storage capacitor; and
a third top electrode disposed over the third storage capacitor.

7. A semiconductor device, comprising:
a substrate;
a first bottom electrode disposed over the substrate;
a first storage capacitor disposed over the first bottom electrode;
a first top electrode disposed over the first storage capacitor;
a second bottom electrode disposed over the first top electrode and electrically coupled to the first bottom electrode;
a second storage capacitor disposed over the second bottom electrode and vertically overlapping the first storage capacitor; and
a second top electrode disposed over the second storage capacitor and electrically coupled to the first top electrode.

8. The semiconductor device as claimed in claim 7, further comprising:
a first conductive via electrically coupling the first bottom electrode to the second bottom electrode;
a metal layer adjacent to the second bottom electrode; and
a second conductive via electrically coupling the metal layer to the first top electrode.

9. The semiconductor device as claimed in claim 8, wherein the second top electrode extends over the metal layer.

10. The semiconductor device as claimed in claim 7, wherein the first top electrode has a first tail portion, and the second top electrode has a second tail portion electrically coupled to the first tail portion.

11. The semiconductor device as claimed in claim 10, wherein a length of the first tail portion is greater than a length of the second tail portion.

12. A method for forming a semiconductor device, comprising:
forming a first capacitor structure over a substrate, comprising:
forming a first bottom electrode;
forming a first storage capacitor over the first bottom electrode; and
forming a first top electrode over the first storage capacitor;
forming a first dielectric layer to cover the first capacitor structure;
forming a plurality of conductive vias in the first dielectric layer; and
forming a second capacitor structure over the first dielectric layer, comprising:
forming a second bottom electrode;
forming a second storage capacitor over the second bottom electrode; and
forming a second top electrode over the second storage capacitor,
wherein the second capacitor structure vertically overlaps the first capacitor structure and is electrically coupled to the first capacitor structure through the conductive vias.

13. The method for forming a semiconductor device as claimed in claim 12, wherein the conductive vias are electrically coupled to the first top electrode and the second bottom electrode.

14. The method for forming a semiconductor device as claimed in claim 13, further comprising:
during the formation of the second bottom electrode, forming a metal layer electrically coupled to the first bottom electrode through the conductive vias.

15. The method for forming a semiconductor device as claimed in claim 12, wherein the conductive vias electrically couple the first bottom electrode to the second bottom electrode.

16. The method for forming a semiconductor device as claimed in claim 15, further comprising:
during the formation of the second bottom electrode, forming a metal layer electrically coupled to the first top electrode through the conductive vias.

17. The method for forming a semiconductor device as claimed in claim 12, further comprising:
forming a second dielectric layer to cover the second capacitor structure;
forming a third capacitor structure over the second dielectric layer, comprising:
forming a third bottom electrode;
forming a third storage capacitor over the third bottom electrode; and
forming a third top electrode over the third storage capacitor;
forming a third dielectric layer to cover the third capacitor structure; and
forming a fourth capacitor structure over the third dielectric layer, comprising:
forming a fourth bottom electrode;
forming a fourth storage capacitor over the fourth bottom electrode; and
forming a fourth top electrode over the fourth storage capacitor,
wherein the fourth capacitor structure vertically overlaps and is electrically coupled to the first capacitor structure, the second capacitor structure, and the third capacitor structure.

18. The method for forming a semiconductor device as claimed in claim 17, wherein the first bottom electrode is electrically coupled to the third bottom electrode,
the first top electrode is electrically coupled to the second bottom electrode,
the second top electrode is electrically coupled to the fourth top electrode, and
the third top electrode is electrically coupled to the fourth bottom electrode.

19. The method for forming a semiconductor device as claimed in claim 17, further comprising:
during the formation of the second bottom electrode, forming a first metal layer;
during the formation of the third bottom electrode, forming a second metal layer; and
during the formation of the fourth bottom electrode, forming a third metal layer and a fourth metal layer,
wherein the first metal layer is electrically coupled to the third metal layer, and the second metal layer is electrically coupled to the fourth metal layer.

20. The method for forming a semiconductor device as claimed in claim 17, wherein the second top electrode and the fourth top electrode have tail portions.
